(19) United States
(12) Patent Application Publication
(10) Pub. No.: US 2025/0171298 A1
(43) Pub. Date: May 29, 2025

(54) METHOD FOR PRODUCING A MICROELECTROMECHANICAL COMPONENT, AND MICROELECTROMECHANICAL COMPONENT

(71) Applicant: Robert Bosch GmbH, Stuttgart (DE)

(72) Inventors: Andreas Winden, Reutlingen (DE); Gregor Schuermann, Reutlingen (DE)

(21) Appl. No.: 18/948,952

(22) Filed: Nov. 15, 2024

(30) Foreign Application Priority Data
Nov. 28, 2023 (DE) 10 2023 211 878.5

(51) Int. Cl. B81C 1/00; G01L 9/00

(52) U.S. Cl. CPC B81C 1/00158; G01L 9/0042; G01L 9/0054; B81C 2201/0132; B81C 2201/014

(57) ABSTRACT

A method for producing a microelectromechanical component having a diaphragm. A substrate with a substrate surface and a buried horizontal etch stop structure is provided. Starting from a front side of the substrate, a vertical etch stop structure, extending substantially perpendicularly to the substrate surface is introduced, which predefines a lateral diaphragm contour of the diaphragm. To expose the diaphragm, a substrate recess is etched starting from a rear side of the substrate to the horizontal etch stop structure and the vertical etch stop structure. A microelectromechanical component with a substrate and a diaphragm, is also provided. A lateral diaphragm contour of the diaphragm is delimited by a vertical trench structure. Starting from a rear side of the substrate that faces away from the diaphragm, a substrate recess runs through the substrate and merges laterally into the vertical trench structure at least in a bottom region facing the diaphragm.

### FIELD

The present invention relates to a method for producing a microelectromechanical component having a diaphragm. The present invention furthermore relates to a microelectromechanical component having a diaphragm.

### BACKGROUND INFORMATION

Certain microelectromechanical components, also known as MEMS components, and methods for their production are described in the related art.

U.S. Patent Application No. US 2010/0140725 A1 describes a piezoresistive pressure sensor made from a BESOI wafer having a first and a second silicon layer and an oxide layer arranged therebetween. The first silicon layer forms an active layer with a diaphragm and piezoresistive elements. The second silicon layer has a recess below the diaphragm and forms a diaphragm carrier. Below the diaphragm, a groove is introduced into the oxide layer. In addition, a method for producing such a pressure sensor is described.

### SUMMARY

According to an example embodiment of the present invention, a method for producing a microelectromechanical component having a diaphragm is provided, wherein a substrate with a substrate surface and a buried horizontal etch stop structure is provided or produced and, starting from a front side of the substrate, a vertical etch stop structure extending substantially perpendicularly to the substrate surface is introduced, wherein the vertical etch stop structure predefines a lateral diaphragm contour of the diaphragm, and wherein, in order to expose the diaphragm, a substrate recess is etched starting from a rear side of the substrate as far as the horizontal etch stop structure and the vertical etch stop structure.

In other words, it is provided, in the production of the component, to produce an in particular circumferential diaphragm boundary by means of precise front-side structuring with a vertical etch stop structure first and then to expose the diaphragm within the predetermined diaphragm boundary by means of rear-side etching.

This makes it possible to produce components with very precisely positioned and precisely contoured diaphragms. Here, the degree of precision of the diaphragm production does not depend on the accuracy of the rear-side etching process for producing the substrate recess, so that, for example, effects of inhomogeneities of the rear-side etching process on the positioning accuracy or shape accuracy of the diaphragm can be reduced or eliminated. A potential front-to-rear offset, which can describe a deviation of the diaphragm position from the position of the substrate recess in the region of the substrate surface, is avoided by means of the proposed method by the targeted front-side structuring to define the lateral diaphragm contour.

In addition, according to an example embodiment of the present invention, the geometric shaping of the diaphragm is not tied to the geometric shape of the substrate recess, but can be designed as desired, independently of the cross-sectional shape of the substrate recess. Accordingly, a geometric shape of the diaphragm contour can deviate from a geometric cross-sectional shape of the substrate recess. In addition, the shape of a rear-side opening of the substrate recess can deviate from the actual diaphragm geometry. This has advantages, for example, for construction and connection processes following component production as well as for chip stability of the component. For example, the produced components can be used to produce small chips with the largest possible rear-side area, wherein the rear-side area can be used as an adhesive area, for example. The very precise and freely selectable diaphragm geometry means that new technical possibilities for the use of such microelectromechanical components can be opened up. With the proposed method, complex geometric shapes of the diaphragm can also be realized, which, for example, has at least one indentation and/or at least one projection.

A component produced according to the method according to the present invention has a diaphragm for which a very high accuracy with regard to its size, positioning, thickness and geometric shape can be achieved, independently of a substrate thickness and of etching tolerances during the production of the substrate recess. This makes it possible overall to produce more precise microelectromechanical components that can meet high demands in terms of their accuracy and robustness. A component produced according to the proposed method has a diaphragm that is accessible from a diaphragm front side and from a diaphragm rear side, so that such a component is suitable for use in a pressure sensor, for example.

According to an example embodiment of the present invention, a microelectromechanical component can, for example, be a component that is produced with semiconductor technology and has mechanical and electrical microstructures. A microelectromechanical component can be suitable for implementation as a system-on-chip (SoC). Microelectromechanical components can be used, for example, as miniaturized sensors or actuators. For example, the microelectromechanical component can be implemented in an environmental sensor such as a pressure sensor.

A diaphragm can be a movable microstructure of the microelectromechanical component. The diaphragm can be a flat microstructure with a width and length greater than the thickness. The diaphragm can be deflectable by interaction with its environment, for example under the action of pressure. Various parameters, such as the material, the geometric shape and the dimensions of the diaphragm or its connection to surrounding component structures, can influence the sensitivity of the diaphragm to external influences. The diaphragm has a lateral diaphragm contour, which in other words can correspond to an outer contour of the diaphragm or a circumferential diaphragm edge at the circumference of the diaphragm. Here, the term “lateral” can indicate that a lateral boundary of the diaphragm in its thickness extension is meant. A distance from one lateral diaphragm contour portion to an opposite lateral diaphragm contour portion can correspond to a local diameter of the diaphragm along its length or width extension.

A substrate can be a flat semiconductor carrier structure with a width and length greater than the thickness. The substrate has two mutually opposing substrate surfaces that form a front side and a rear side of the substrate. The substrate surfaces each have a significantly larger surface area than a substrate end face. The front side of the substrate can form an active side of the substrate, on which, for example, the movable microstructures of the microelectromechanical component, such as the diaphragm, are produced and/or measuring elements such as piezoresistors are applied, for example doped in. The rear side of the substrate can form a mechanical carrier structure and allow rear access to the diaphragm through a substrate recess.

The substrate recess corresponds to an opening in the substrate, which can extend in a tunnel-like manner from the rear-side substrate surface through the substrate to the intended diaphragm. The substrate recess forms a cavity that is open to the environment of the microelectromechanical component. Due to the tunnel-like nature of the substrate recess, it can also be referred to as a trench or channel. The substrate recess can widen in the direction of the diaphragm, i.e., have an enlargement in cross section. In particular, the cross-sectional area of the substrate recess immediately below the diaphragm can correspond to the diaphragm cross-sectional area predefined by the vertical etch stop structure, while the cross-sectional area of the substrate recess in the rear-side substrate surface is smaller than immediately below the diaphragm. During the production process, the substrate recess is used for the targeted exposure of the diaphragm predefined on the front side. During operation of the microelectromechanical component, the substrate recess is used as a rear-side access opening to the diaphragm in order to allow interaction of the diaphragm with the environment of the component.

According to an example embodiment of the method of the present invention, the substrate is provided having a buried horizontal etch stop structure, or such a structure is produced during the production process. A substrate with a buried horizontal etch stop structure can advantageously be provided by a so-called silicon-on-insulator wafer (SOI wafer), as explained below. The horizontal etch stop structure can, for example, be a silicon oxide layer (SiO₂) and is in this case also called buried oxide (BOx). The horizontal etch stop structure can extend in parallel with the substrate surfaces of the substrate. A buried horizontal etch stop structure can be understood as being enclosed in or surrounded by the substrate material. The buried horizontal etch stop structure can therefore be arranged at a distance from a substrate surface. For example, the substrate can have two silicon layers between which the horizontal etch stop structure is sandwiched. The horizontal etch stop structure forms a stop layer for the rear-side etching process, which is suitable for removing the substrate material and stops at the etch stop structure. In principle, an etch stop structure can be a material layer that has a higher etch selectivity or etch resistance than adjacent material layers and can prevent an etching process or etching progress into material layers protected by the etch stop structure. For example, the material layer can be chemically and/or physically more resistant than adjacent layers and/or have a significantly lower etch rate than adjacent layers.

According to an example embodiment of the present invention, a vertical etch stop structure can be produced in the substrate by suitable processing of the front side of the substrate, for example by a structuring method such as a trench process, wherein, according to one design option, the etch stop structure initially produced as a free space is coated or filled with a suitable etch stop material. The vertical etch stop structure can in particular be introduced into the substrate as a closed contour in order to be able to predefine a circumferential lateral diaphragm contour of the diaphragm. The vertical etch stop structure can, for example, form a circumferential trench around the intended diaphragm edge. The vertical etch stop structure can, for example, be an SiO₂-based etch stop material, in particular a thermal silicon dioxide.

Etching as far as the horizontal etch stop structure and the vertical etch stop structure can be understood to mean that the etching process proceeds into the depth of the substrate from the rear side toward the horizontal etch stop structure. The etching process stops at the horizontal etch stop structure in the depth direction and at the vertical etch stop structure in the lateral direction, i.e., transversely to the depth direction. The horizontal etch stop structure and the vertical etch stop structure can merge into or intersect each other and thus jointly delimit a multi-dimensional etch stop region on the intended diaphragm. The substrate recess can be produced such that it is laterally adjacent to the vertical etch stop structure at least in a bottom region facing the intended diaphragm.

The etching processes mentioned in connection with the production of the microelectromechanical component according to the present invention can advantageously be carried out using dry etching methods, such as plasma etching. In a plasma etching process, sulfur hexafluoride (SF₆) can be used as an etching medium, for example. In principle, however, wet-chemical etching methods can also be used. Furthermore, the component can be processed in further optional production steps using other processing methods, for example thinned using a grinding process and/or chemically-mechanically polished (CMP process).

According to one example embodiment of the present invention, the vertical etch stop structure can be produced by producing a trench in the substrate and by passivating side wall faces of the trench with a passivation layer. This allows the vertical etch stop structure to be produced in a simple and efficient manner. In addition, exact positioning and lateral contouring of the trench is possible, for example by means of photolithography technology, wherein the trench geometry can in principle be freely selected, for example with regard to its desired cross-sectional shape and dimensions. The trench is introduced from the front side of the substrate and can, for example, be produced by means of a trench process in which a silicon trench for the local removal of substrate material, an oxide etching step for the local removal of the buried horizontal etch stop structure and a further silicon trench for the local removal of further substrate material can follow one another, wherein the etching process is adapted to the subsequent material layer in each case depending on time or based on monitoring of reaction gases. This allows the material layers of the substrate, including the etch stop material of the buried horizontal etch stop structure, to be removed over the intended trench diameter and along the desired trench depth. In particular, the trench can be produced circumferentially with a closed contour in order to be able to predefine a circumferential diaphragm contour. According to a numerical example, which is to be regarded as non-limiting, a trench diameter can be approximately 1 to 2 μm and a trench depth can be approximately 10 to 30 μm, for example, wherein the trench diameter is regarded as a trench extension running in parallel with a substrate surface of the substrate and the trench depth is regarded as a trench extension running perpendicularly to a substrate surface of the substrate. The term “side wall faces of the trench” can in particular mean all existing inner wall faces of the trench, regardless of their vertical or horizontal orientation.

According to an example embodiment of the present invention, for passivating the side wall faces of the trench, they can be covered with a dielectric material as a passivation layer. For this purpose, for example, the dielectric material is deposited as a layer on the front-side substrate surface, wherein the dielectric material can penetrate into the trench. The dielectric material that forms the etch stop material of the vertical etch stop structure as a passivation layer can, for example, be an SiO₂-based etch stop material. The material of the passivation layer can be selected with regard to a high suitability for conformal deposition on the trench side walls, sufficient etch selectivity to the adjacent substrate material, and high sealing over the vertical and lateral extent of the trench against the etching medium used to remove the substrate material. Examples of possible materials for the passivation layer are thermal silicon dioxide, CVD/PECVD/LPCVD silicon dioxide, ALD silicon dioxide, ALD aluminum oxide or SiRiN (silicon rich nitride), wherein CVD stands for chemical vapor deposition, PECVD for plasma-enhanced chemical vapor deposition, LPCVD for low-pressure chemical vapor deposition, and ALD for atomic layer deposition. The passivation of the side wall faces is carried out in particular as conformal side wall passivation, which can be understood as an ideally complete passivation with as uniform a layer thickness as possible along all wall faces of the trench. A passivation layer thickness that is generally suitable for a trench with the dimensions given above by way of example can, for example be, approximately 100 nm.

According to one example embodiment of the present invention, a silicon-on-insulator wafer can be provided as the substrate. This makes it possible to provide a substrate with a buried horizontal etch stop structure in a simple and cost-effective manner. A silicon-on-insulator wafer (SOI wafer) is a silicon wafer with a buried dielectric layer, in particular a silicon oxide layer. An SOI wafer can, for example, be produced by wafer bonding. In this case, two oxidized silicon wafers can be aligned with each other and bonded to each other via the silicon oxide layer. This produces a wafer with three layers, wherein the silicon oxide layer is located between two silicon layers. One of the two silicon layers can be thinned and polished in order to form a so-called active layer, also called device layer. The active layer can have a layer thickness of a few micrometers. In the proposed method, the buried dielectric layer is used as a horizontal etch stop structure at which a rear-side etching process for producing the substrate recess can stop and allow exposure of the diaphragm to be formed.

According to one example embodiment of the present invention, the substrate recess can be etched by means of a stage-by-stage trench process. The production of the substrate recess can thereby be precisely controlled and made efficient. The etching of the substrate recess can in particular follow front-side processing in which the vertical etch stop structure is introduced into the substrate. The stage-by-stage trench process can, for example, be a dry etching process analogous to the so-called Bosch process, in which etching and passivation steps alternate in order to etch as anisotropically as possible perpendicularly to the substrate surface. The passivation steps can include polymer deposition on the wall faces of the substrate recess. Depending on the desired design of the trench process, the trench process can, for example, be a time-controlled high-rate trench process or stop at the buried horizontal etch stop structure. The trench process can be designed such that it ends within the substrate region laterally delimited by the vertical etch stop structure, taking into account given process tolerances. Depending on the selected embodiment, the stage-by-stage trench process can have regular or irregular stages, for example a final etching stage with a longer etching time.

According to one example embodiment of the present invention, the stage-by-stage trench process can have a plurality of anisotropic etching stages and one isotropic etching stage. While the basic shape of the substrate recess in the direction of the diaphragm can be produced by means of the anisotropic etching stages, the substrate region, laterally delimited by the vertical etch stop structure, below the horizontal etch stop structure can be efficiently removed by means of the isotropic etching stage in a more extensive etching step, wherein the isotropic etching process stops at the vertical and horizontal etch stop structures. The isotropic etching stage can have a longer duration than an anisotropic etching stage and can be adjusted by changing trench parameters. Alternatively, it is possible to switch to another etching medium, such as xenon fluoride (XeF₂) or chlorine trifluoride (CIF₃). An anisotropic etching stage can also be called a loop since it can have an etching step and a passivation step, which steps can be repeated with each loop. The anisotropic etching stages, which can, for example, be realized as a time-dependent anisotropic high-rate trench, can in particular be repeated until the substrate recess has reached a plane of the vertical etch stop structure. In this case, a polymer layer can be deposited on the bottom of the substrate recess, which polymer layer is broken up locally at a bottom region of the substrate recess in the subsequent isotropic etching step, whereby a widening of the substrate recess to the vertical etch stop structure is limited to the bottom region of the substrate recess. Alternatively, it is possible to continue the anisotropic etching process until it stops at the horizontal etch stop structure, which can be controlled, for example, in a time-dependent manner or in response to a detection of reaction gases. Subsequently, an isotropic etching step can be carried out to remove the substrate material as far as the vertical etch stop structure.

Due to the substrate recess produced into the depth, an increasing edge rounding of the substrate recess is to be expected along the trench flank in the direction of the diaphragm to be exposed, i.e., as the etching depth increases. Accordingly, it would not be possible to produce diaphragms with defined corners or acute angles using simple rear-side etching to produce a diaphragm structure. However, this potential disadvantage is overcome by the lateral predefinition of the diaphragm contour by the vertical etch stop structure since the diaphragm edge is not delimited by the edge of the substrate recess, but by the previously introduced vertical etch stop structure. If the etch stop material of the vertical etch stop structure is removed after the diaphragm has been exposed, if desired, the substrate recess etched into the rear side of the substrate merges directly into the vertical etch stop structure without affecting the geometry thereof at the lateral diaphragm edge. Thus, edge rounding of the substrate recess has no effect on the accuracy of the position and on the contour sharpness of the diaphragm contour, and the diaphragm contour can have sharp angular or angled contours if desired.

According to one example embodiment of the present invention, after the substrate recess has been produced, the horizontal etch stop structure and/or the vertical etch stop structure can be removed at least in regions. As a result, the exposure of the diaphragm can be completed and, for example, a pure silicon diaphragm with high sensitivity and stability can be provided. In this case, etch stop material of the horizontal etch stop structure and of the vertical etch stop structure can be removed via the substrate recess using a further etching process that is suitable for removing the etch stop material formed from silicon dioxide, for example.

According to one example embodiment of the present invention, the vertical etch stop structure can be sealed with a sealing layer. This allows the vertical etch stop structure to be protected from material ingress or etching attack during further processing of the front side of the substrate. In particular, at least one front-side opening of the etch stop structure that is directed toward the environment can be sealed with the sealing layer. The embodiment is in particular suitable for a vertical etch stop structure formed as a trench with passivated side wall faces. The sealing material can, for example, be deposited as a layer on the passivation layer, which may have been previously deposited on the front-side substrate surface for passivating the side walls of the trench, and can in the process penetrate into a free space present between the passivated side walls of the trench, so that the trench and in particular a trench opening directed toward the environment is sealed. For example, an LPCVD silicon dioxide can be used as the sealing material for the sealing layer, wherein the trench can advantageously have been passivated with a thermal silicon dioxide and the trench is therefore filled with two different silicon dioxides. The trench can be sealed sufficiently tightly with LPCVD silicon dioxide. Alternatively, other materials are also suitable as sealing material, for example silicon nitride or polysilicon. The layer thickness of the sealing layer can, for example, be 1 to 2 μm.

According to one example embodiment of the present invention, after the vertical etch stop structure has been produced or after the produced vertical etch stop structure has been sealed, the substrate surface on the front side of the substrate can be exposed at least in regions. This allows the exposed substrate surface to be used for further processing, for example for a subsequent epitaxial growth step. For exposure, an etch stop material layer that has been deposited on the substrate surface, for example to passivate a vertical etch stop structure formed as a trench, as well as an optional sealing layer can, for example, be removed by etching by means of photolithography technology while masking the vertical etch stop structure. Alternatively, it is possible to thin and planarize the etch stop material layer and an optional sealing layer over the entire area by etching or polishing until the substrate surface is exposed, provided that it is ensured by means of suitable process parameters that a sealed opening in the vertical etch stop structure is not reopened.

According to one example embodiment of the present invention, a functional layer can be applied to or produced on the substrate, with which functional layer the vertical etch stop structure is enclosed and a diaphragm layer is formed. This protects the vertical etch stop structure and produces a base structure for the diaphragm. In terms of time, the functional layer can in particular be applied to or produced on the substrate after the vertical etch stop structure has been produced or after the produced vertical etch stop structure has been sealed or after the substrate surface has been exposed at least in regions on the front side of the substrate. In particular, the functional layer can be applied or produced before a substrate recess is introduced. According to one exemplary embodiment of the present invention, the application or production of the functional layer can be carried out by epitaxially growing a substrate material of the substrate. The thickness of the diaphragm layer, which may, for example, correspond to the thickness of the functional layer or the combined thickness of the functional layer and an active layer of the substrate, can define the diaphragm thickness. Such a diaphragm thickness can, for example, be approximately 10 μm. Furthermore, electrical connection components, such as piezoresistors, can be doped into the functional layer, for example. If it is a silicon substrate, the growth process can be carried out as silicon epitaxy, and the functional layer can advantageously be formed by a silicon layer. Any seal of the vertical etch stop structure that may be present can be covered by the functional layer, for example by being overgrown with substrate material by means of the growth process, and in this case prevents substrate material from penetrating into the vertical etch stop structure, which could potentially impair the etch resistance of the etch stop structure.

According to one example embodiment of the present invention, at least one measuring element can be applied in the diaphragm at a predetermined distance from the vertical etch stop structure. The measuring element can, for example, be a piezoresistor. For example, the piezoresistor can be doped into the functional layer described above. The measuring element can, for example, be arranged on a surface of the functional layer that faces away from the horizontal etch stop structure. The measuring element can be arranged on a front side of the produced microelectromechanical component, wherein the front side of the component is opposite the rear side of the substrate. By means of the measuring element, a, for example pressure-induced, elastic deflection or deformation of the diaphragm can be detected and converted into a measuring signal. Advantageously, multiple, for example two, three, four or more measuring elements can be applied in order to allow a more precise evaluation of the diaphragm behavior. By applying the measuring element at a predetermined distance from the vertical etch stop structure, a very precise orientation of the measuring element relative to the diaphragm edge can be carried out. This can have a positive effect on the sensitivity of the component. By accurately positioning the piezoresistor, the sensitivity of the component can be precisely adjusted. For example, a centered arrangement of a plurality of measuring elements can make high sensitivity of the component possible.

The vertical etch stop structure provided according to the method according to the present invention thus provides the further advantage that measuring elements can be positioned very precisely in relation to the diaphragm contour defined by means of the vertical etch stop structure. The vertical etch stop structure thus forms an orientation point not only for the rear-side etching of the substrate recess and exposure of the diaphragm but also for the front-side processing of the component.

Before, during or after the application of the measuring element, further electrical functional components can be introduced into the component, for example into the functional layer and/or the substrate. For example, circuit elements and piezoresistors can be produced in the component in a CMOS process. In addition to doping of layer planes, it is also, for example, possible to produce conductor tracks, circuit elements and/or metal bond pads and to apply an electrical connection for a signal processing unit, for example an ASIC.

The present invention also relates to a microelectromechanical component with a substrate and a diaphragm. According to an example embodiment of the present invention, a lateral diaphragm contour of the diaphragm is delimited by a vertical trench structure and, starting from a rear side of the substrate that faces away from the diaphragm, a substrate recess runs through the substrate and merges laterally into the vertical trench structure at least in a bottom region facing the diaphragm. The advantages of a precisely positioned and geometrically exactly defined diaphragm edge can also be achieved with the proposed microelectromechanical component. In addition, a measuring element can be precisely oriented relative to the diaphragm contour. The vertical trench structure can, for example, run substantially perpendicularly to a substrate surface of the substrate. The substrate recess provides a component with a diaphragm accessible from two opposite sides. The microelectromechanical component can be produced in a simple and efficient manner with high precision. The microelectromechanical component can in particular be produced according to the method described above. For example, the substrate can be a silicon-on-insulator wafer. For example, the vertical trench structure can be passivated and/or have a sealing material at least in regions. At a predetermined distance from the vertical etch stop structure, at least one measuring element, for example a piezoresistor, can be applied in the diaphragm. The diaphragm can be formed at least partially by a functional layer that is applied to or produced on the substrate and is formed, for example, from a silicon material. The measuring element can be doped into the functional layer. The vertical trench structure can extend through the functional layer in portions and through the substrate in portions. The vertical trench structure can have a circumferential closed contour.

According to one example embodiment of the present invention, the microelectromechanical component can be designed as a sensor component and/or as an actuator component. Accordingly, the microelectromechanical component can be configured for sensory detection and/or for influencing at least one chemical or physical variable that can be detected or influenced by means of an elastically deflectable or deformable diaphragm. The microelectromechanical component can, for example, be designed as a sensor component designed as an environmental sensor. The microelectromechanical component can, for example, be designed as an actuator component designed as a microfluidic component, such as a micropump. Furthermore, with the microelectromechanical component, it is possible to realize combination components which are designed as a combined sensor and actuator component and are suitable for the active control of a predetermined controlled variable, for example. Moreover, it is possible to design the microelectromechanical component as an acoustic sensor or actuator component, for example as a microphone or loudspeaker. The microelectromechanical component can also be implemented as a system-on-chip (SoC) and thus arranged on a chip. The microelectromechanical component can be electrically connected to a signal processing unit for applying and/or processing signals, for example to an ASIC, or can have such a signal processing unit.

According to an advantageous development of the above-described embodiment of the present invention, the microelectromechanical component can be designed as a pressure sensor. Through the precisely contoured diaphragm, a precisely adjustable pressure sensitivity of the pressure sensor can be achieved. Depending on the design, the pressure sensor can be designed as an absolute pressure sensor or as a relative pressure sensor. Optionally, an additional cavity can be arranged in the component with a predefined reference pressure in order to allow measurements with reference-based measuring principles.

According to one example embodiment of the present invention, a geometric shape of the diaphragm contour can deviate from a geometric cross-sectional shape of the substrate recess. Due to the diaphragm edge defined by the vertical trench structure, the diaphragm contour is independent of the geometric design of the substrate recess. Accordingly, the cross-sectional shape of the substrate recess can have any different cross-sectional shape than the diaphragm, and the diaphragm is not bound to the shape of the substrate recess. A deviation of the geometric shape of the diaphragm contour from the shape of the substrate recess can also be referred to as geometry conversion since the cross-sectional shape of the substrate recess can be converted into a different diaphragm shape via the vertical trench structure defining a lateral diaphragm boundary. Due to the vertical trench structure, a front-to-rear offset is irrelevant for the geometry and position of the diaphragm, for example also with regard to other elements that can be assigned to the front side of the component, such as measuring elements, conductor tracks or circuit elements. There is a high degree of design freedom with regard to the geometric design of the diaphragm and of the substrate recess, which can each be optimized with regard to individual requirements. For a geometry conversion, for example, a substrate recess with a rectangular cross section can be combined with a hexagonal, circular or elliptical diaphragm or, for example, a substrate recess with a circular cross section can be combined with a quadrangular diaphragm. Angular shapes of the diaphragm can be implemented without difficulty since the diaphragm contour is not defined by the substrate recess, but by the lateral delimitation by means of the vertical trench structure, and thus, for example, an increasing edge rounding of the substrate recess with increasing depth in the substrate has no effect on the contour sharpness of the diaphragm contour. Thanks to the possibility of designing the diaphragm independently of the substrate recess, the geometric shape of the diaphragm can, for example, be adapted to the intended operating conditions of the microelectromechanical component. For example, round diaphragm shapes can be advantageous for acoustic microelectromechanical components such as microphones. Other diaphragm shapes can support a cantilevered suspension of the diaphragm via a spring structure, for example in order to achieve a stress decoupling of the diaphragm from a surrounding layer system.

According to one example embodiment of the present invention, the diaphragm contour can have a complex geometric shape with at least one indentation and/or at least one projection. Furthermore, such a complex geometric shape can, for example, be based on at least two different combined basic geometric shapes or on at least two identical combined basic geometric shapes with different dimensions. For example, a complex geometric shape can have a plurality of angles or radii in a regular or irregular arrangement. A complex geometric shape is different from a simple geometric shape, which can, for example, be a circle, an ellipse or a regular quadrilateral. The complex geometric shape can, for example, be a polygon, which is formed by a geometric figure with a closed line and can have concave and/or convex portions. The complex geometric shape can, for example, have round or angular projections and/or round or angular indentations on its circumference. Due to the lateral diaphragm contour delimited by the vertical trench structure and due to the high design freedom of the trench structure, almost any filigree and varied diaphragm contours can be provided. As a result, it is possible to influence a characteristic diaphragm behavior very precisely or else to open up new technical fields of application for the microelectromechanical component.

In general, in the context of this application, the words “a/an,” unless expressly defined otherwise, are not to be understood as numerals, but as indefinite articles with the literal meaning of “at least one.”

The present invention allows for various embodiments and is explained in more detail below using exemplary embodiments with the figures.

### BRIEF DESCRIPTION OF THE DRAWINGS

FIGS. 1 and 2 show a microelectromechanical component with a diaphragm according to an exemplary embodiment of the present invention in a cross-sectional view from the side and in a partially transparent view from above.

FIG. 3 shows a simplified flow diagram of a method for producing the microelectromechanical component, according to an example embodiment of the present invention.

FIG. 4-13 show selected exemplary method steps of the method for producing the microelectromechanical component using cross-sectional views from the side, according to the present invention.

FIG. 14-19 show further exemplary embodiments of microelectromechanical components with a diaphragm in partially transparent views from above, according to the present invention.

### DETAILED DESCRIPTION OF EXAMPLE EMBODIMENTS

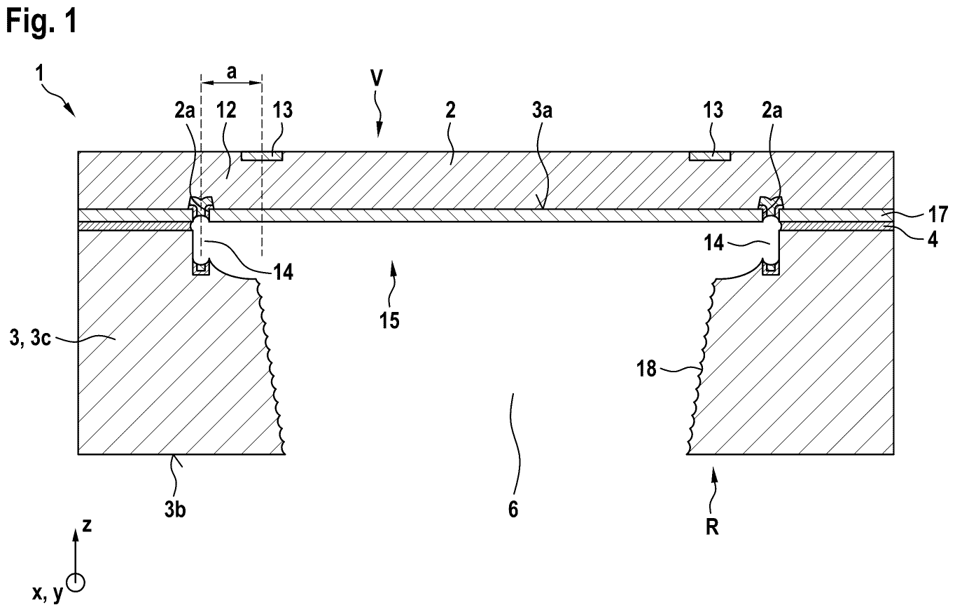

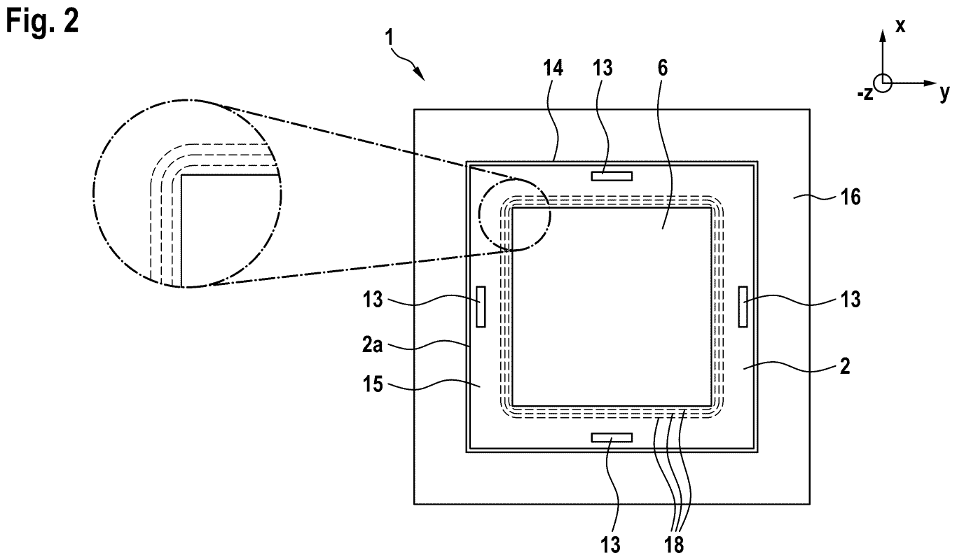

FIGS. 1 and 2 schematically show a microelectromechanical component 1 with a diaphragm 2 in different views. The component 1 has a substrate 3 with a front-side substrate surface 3a and a rear-side substrate surface 3b. The component 1 has a front side V and a rear side R opposite the front side V. According to the exemplary embodiment shown, the substrate 3 is formed by an SOI wafer and has a buried horizontal etch stop structure 4 shown removed in regions in FIG. 1. The diaphragm 2 is formed by an active layer 17 of the substrate 3, also called device layer, and by a functional layer 12 applied to the active layer 17. As shown in FIGS. 1 and 2, the diaphragm 2 extends predominantly in a planar manner in an x, y main extension plane. A lateral diaphragm contour 2a of the diaphragm 2 is delimited by a circumferential vertical trench structure 14. The vertical trench structure 14 extends predominantly in a z dimension running perpendicularly to the x, y main extension plane of the diaphragm 2 and runs substantially perpendicularly to the substrate surfaces 3a, 3b of the substrate 3.

Starting from the rear side R, a substrate recess 6 runs through the substrate 3 in a tunnel shape and with increasing cross-sectional enlargement and merges into the lateral trench structure 14 in a bottom region 15. The substrate recess 6 is used to expose the diaphragm 2 during production of the component 1 and forms an access opening to the diaphragm 2 during operation of the component 1 in order to allow interaction of the diaphragm 2 with the environment of the component 1. On the front side V of the component 1, measuring elements 13 designed as piezoresistors are arranged on the diaphragm 2 by doping them into the functional layer 12 in order to detect an elastic deflection or deformation of the diaphragm 2 and to convert it into an electrical measuring signal, which can be transmitted to a signal processing unit (not shown) via electrical connection structures (not shown in detail). The measuring elements 13 have a predefined x, y offset from the diaphragm contour 2a, which offset is indicated by way of example as distance a in FIG. 1.

As shown in FIG. 2, the component 1 is arranged in a chip frame 16 and thus implemented as a system-on-chip. In addition, it can be seen that a trench flank 18 of the substrate recess 6 that runs between the rear side R of the component 1 and the diaphragm 2 has an increasing edge rounding, which, however, has no effect on the diaphragm contour 2a, defined laterally by the vertical trench structure 14, and its contour sharpness. Instead, the diaphragm contour 2a is sharply delimited and precisely formed by the vertical trench structure 14.

The microelectromechanical component 1 shown in FIGS. 1 and 2 has the advantage of a precisely positioned and geometrically exactly defined diaphragm edge. In addition, the measuring element 13 can be precisely oriented relative to the diaphragm contour 2a at a predetermined distance a in order to be able to precisely adjust a sensitivity of the component 1. The component 1 can, for example, be designed as a sensor component or as an actuator component and can advantageously be implementable in an environmental sensor such as a pressure sensor. The precisely contoured diaphragm 2 allows the pressure sensitivity or a characteristic deflection or deformation behavior of the diaphragm 2 to be precisely adjusted.

The microelectromechanical component 1 shown in FIGS. 1 and 2 can be produced in a simple and efficient manner with high accuracy, as explained in more detail below.

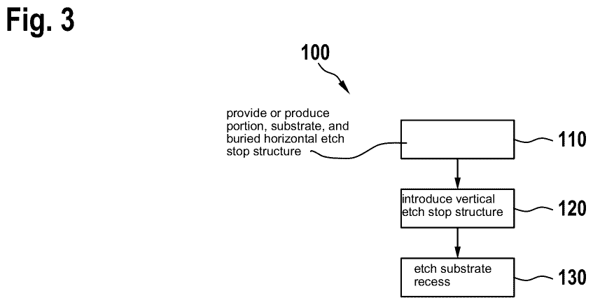

In FIG. 3, a schematic, highly simplified flow diagram of a method 100 for producing the microelectromechanical component 1 is shown as a block diagram. Accordingly, in a first method portion 110, a substrate 3 with a substrate surface 3a, 3b and a buried horizontal etch stop structure 4 is provided or produced. In a second method portion 120, starting from a front side V of the substrate 3, a vertical etch stop structure 5 extending substantially perpendicularly to the substrate surface 3a, 3b is introduced, wherein the vertical etch stop structure 5 predefines a lateral diaphragm contour 2a of the diaphragm 2. In a third method portion 130, in order to expose the diaphragm 2, a substrate recess 6 is etched starting from a rear side R of the substrate 3 as far as the horizontal etch stop structure 4 and the vertical etch stop structure 5. With the method 100 shown, it is possible to produce components 1 with very precisely positioned and precisely contoured diaphragms 2, since the diaphragm contour 2a is defined by the vertical etch stop structure 5 and can be designed independently of a cross-sectional shape or position of the substrate recess 6.

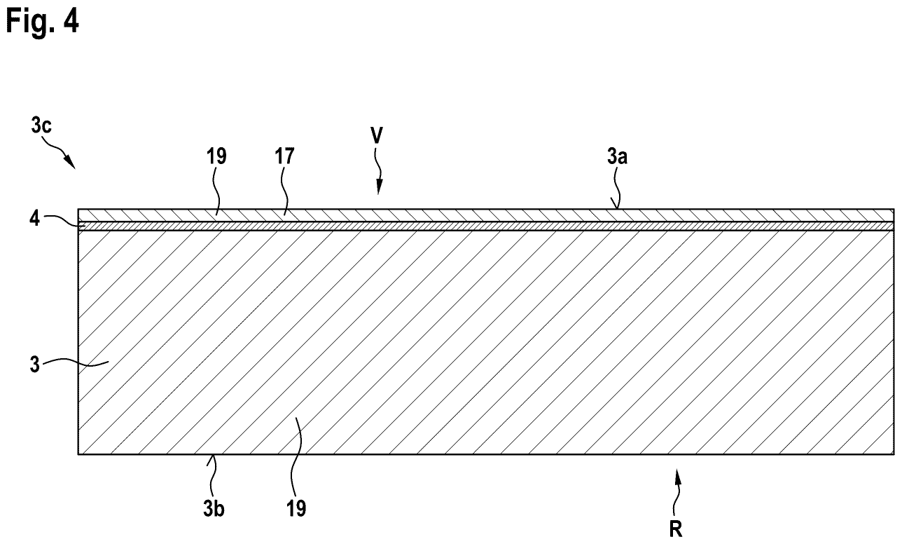

Individual possible method steps of the method 100 for producing the microelectromechanical component 1 are explained in more detail by way of example below with reference to FIGS. 4 to 13.

According to FIG. 4, a substrate 3 formed as an SOI wafer 3c is provided. The substrate 3 has a front-side substrate surface 3a on a front side V and a rear-side substrate surface 3b on a rear side R. An SOI wafer 3c is a silicon-on-insulator wafer having a first and second silicon layer 19 with a dielectric layer, for example a silicon oxide layer, in between. According to the method explained, the dielectric layer is used as a buried horizontal etch stop structure 4 and extends substantially in parallel with and at a distance from the substrate surfaces 3a, 3b. According to the exemplary embodiment shown, the silicon layers 19 have different thicknesses. The thinner and usually planarized silicon layer 19 is called the active layer 17 or device layer. As explained below, a functional layer 12 is applied to the active layer 17 in a later method step, which functional layer together with the active layer 17 forms a diaphragm layer 20 of the component 1.

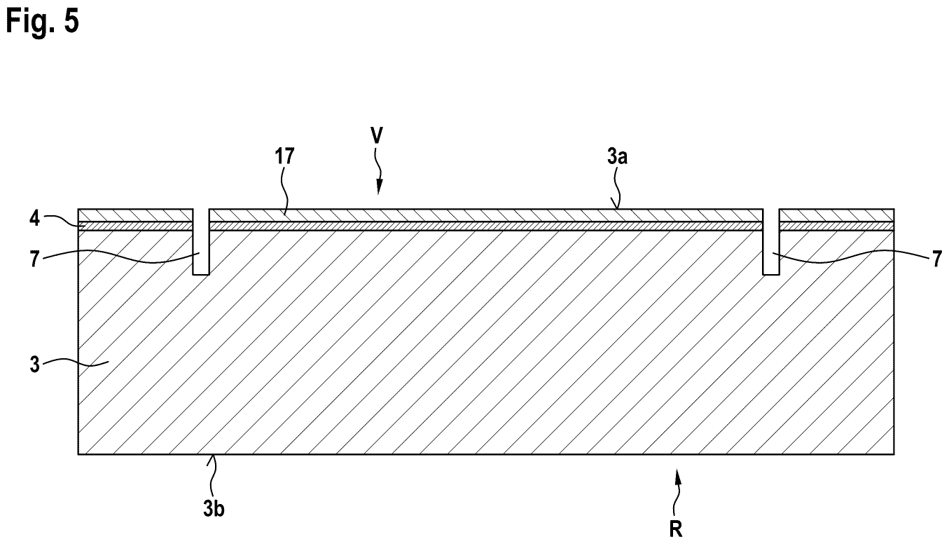

According to FIG. 5, a circumferential trench 7 is produced in the substrate 3, which trench later forms the etch stop structure 5 for the lateral predefinition of the diaphragm contour 2a. The trench 7 can be precisely positioned and contoured by means of photolithography technology, for example, wherein the cross-sectional shape and dimensions of the trench 7 can in principle be freely selected but must be suitable for the defined contouring and delimitation of the diaphragm 2. The trench 7 is introduced from the front side V of the substrate 3 and can be produced, for example, by means of a trench process, for example with successive silicon and silicon oxide trenches. According to the exemplary embodiment shown, the trench 7 is produced as a circumferential closed contour in order to define a circumferential diaphragm contour 2a on the circumference of the diaphragm 2.

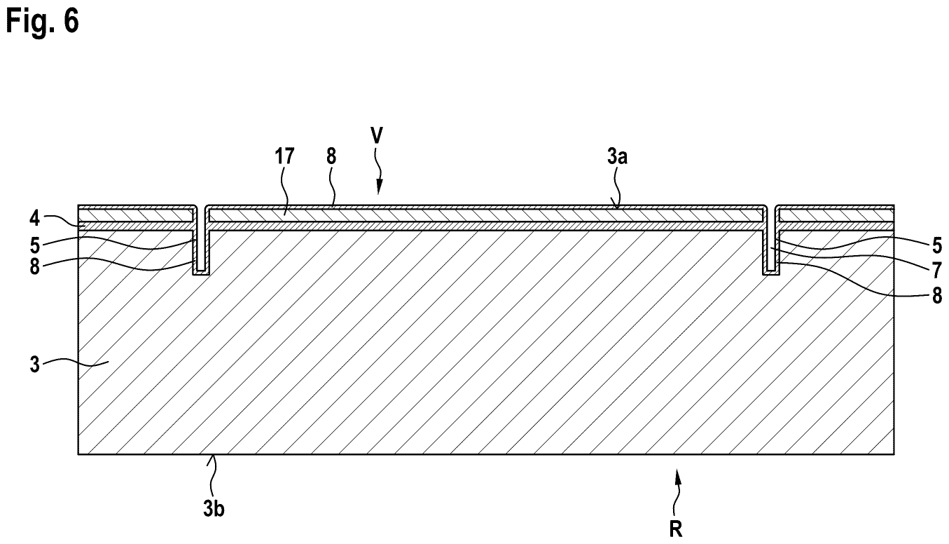

FIG. 6 shows that a passivation layer 8 has been deposited on the substrate 3. The passivation layer 8 penetrates into the trench 7 and coats the side wall faces of the trench 7. The passivation layer 8 can, for example, contain a thermal silicon dioxide, with which a conformal passivation of the side wall faces of the trench 7 can advantageously be achieved. The passivation layer 8 forms an etch stop material of the vertical etch stop structure 5 provided by the coated trench 7.

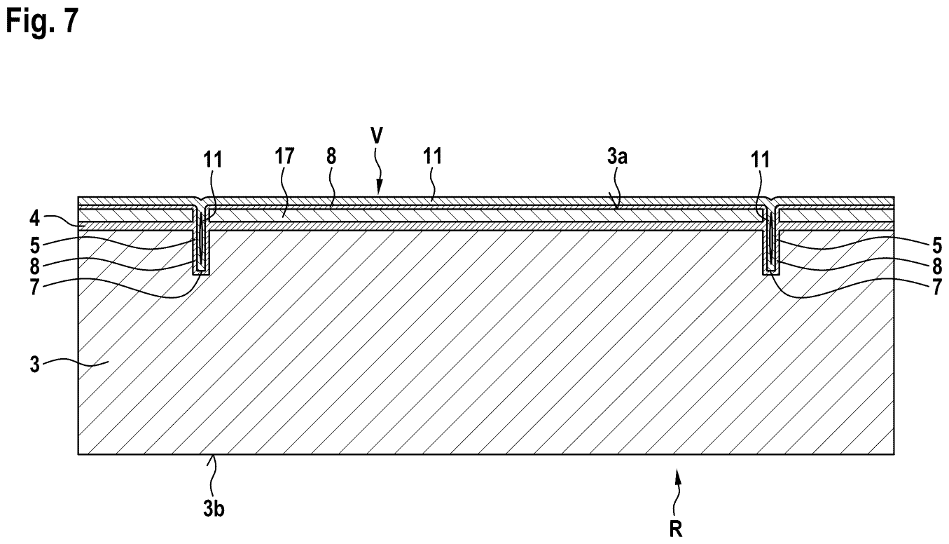

FIG. 7 shows that the vertical etch stop structure 5 formed as a trench 7 has been sealed with a sealing layer 11 in order to protect the vertical etch stop structure 5 from material ingress during the further processing of the front side V of the substrate 3. For this purpose, a sealing layer 11 has been deposited on the passivation layer 8. The sealing layer 11 penetrates into a gap between the passivated side walls of the trench 7 and fills the gap completely or almost completely. In particular, the sealing layer 11 seals the trench 7 at a trench opening on the front-side substrate surface 3a of the substrate 3 as tightly as possible. For example, an LPCVD silicon dioxide can be used as the sealing material for the sealing layer 11.

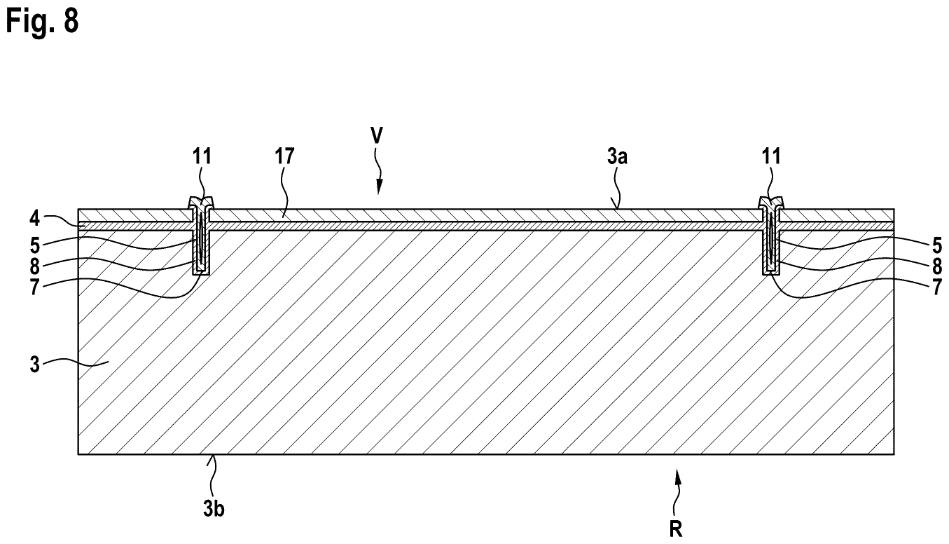

It can be seen in FIG. 8 that, after the vertical etch stop structure 5 has been sealed, the front-side substrate surface 3a has been exposed. For this purpose, the vertical etch stop structure 5 was masked, for example by means of photolithography technology, and the passivation layer 8 and the sealing layer 11 were then removed by means of an etching process suitable for removing silicon dioxide material. Owing to the masking of the vertical etch stop structure 5, the sealing layer 11 and the passivation layer 8 were preserved in the region of the vertical etch stop structure 5 so that the latter continues to be reliably protected against material ingress.

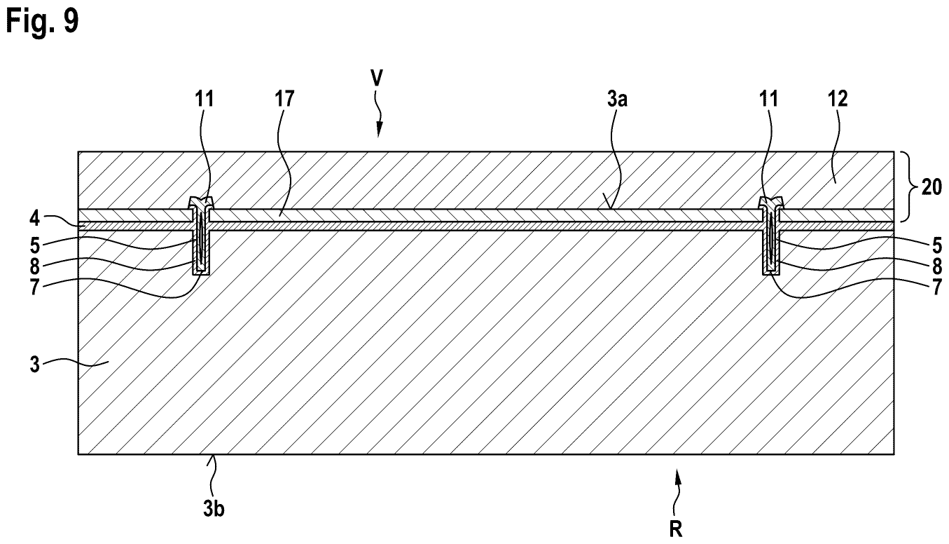

FIG. 9 shows that a functional layer 12 has been produced on the front-side substrate surface 3a, with which functional layer the vertical etch stop structure 5 is enclosed and a diaphragm layer 20 is formed. As a result, the vertical etch stop structure 5 is arranged in a protected manner and a base structure of the diaphragm 2 is produced. The thickness of the diaphragm layer 20 can define the diaphragm thickness. The functional layer 12 can be produced, for example, by epitaxially growing the silicon material of the active layer 17, wherein the sealing region of the vertical etch stop structure 5 is overgrown by the silicon material and is reliably protected by the sealing layer 11 against contamination of the vertical etch stop structure 5 with silicon material.

In FIG. 10, it can be seen that measuring elements 13 are applied in the diaphragm layer 20, for example doped thereinto, at a predetermined distance a from the vertical etch stop structure. The measuring elements 13 are arranged on a front side V of the component 1 and can, for example, be designed as piezoresistors. By means of the measuring elements 13, pressure-induced elastic deflections or deformations of the diaphragm 2 can, for example, be detected and converted into a measuring signal. By applying the measuring elements 13 at a predetermined distance a from the vertical etch stop structure 5, a very precise orientation of the measuring elements 13 relative to the precisely defined diaphragm contour 2a is possible and a sensitivity of the component 1 can thereby be precisely adjusted. In the method step shown in FIG. 10, the production of further electrical functional components can also be carried out, such as the application of circuit elements, conductor tracks, metal bonding pads and electrical connections for connecting the component 1 to a signal processing unit, but this is not shown in detail.

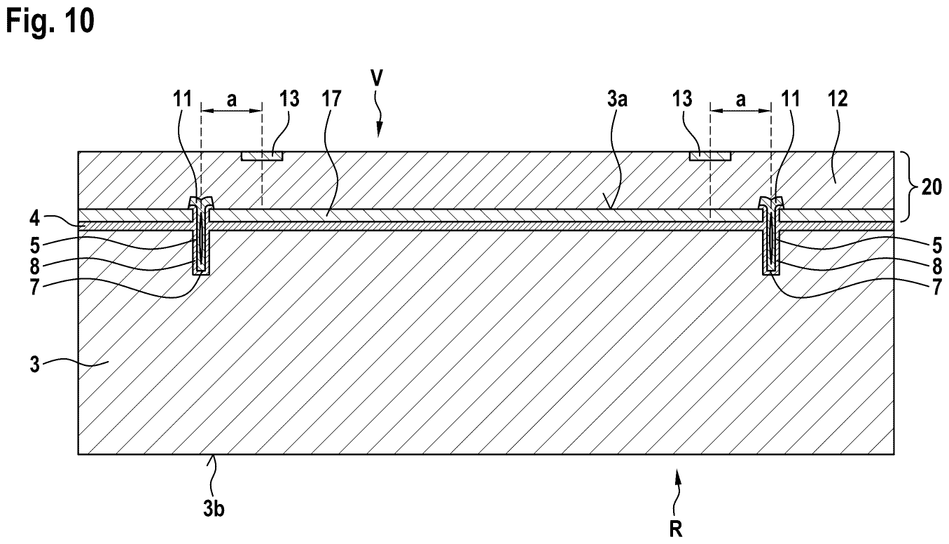

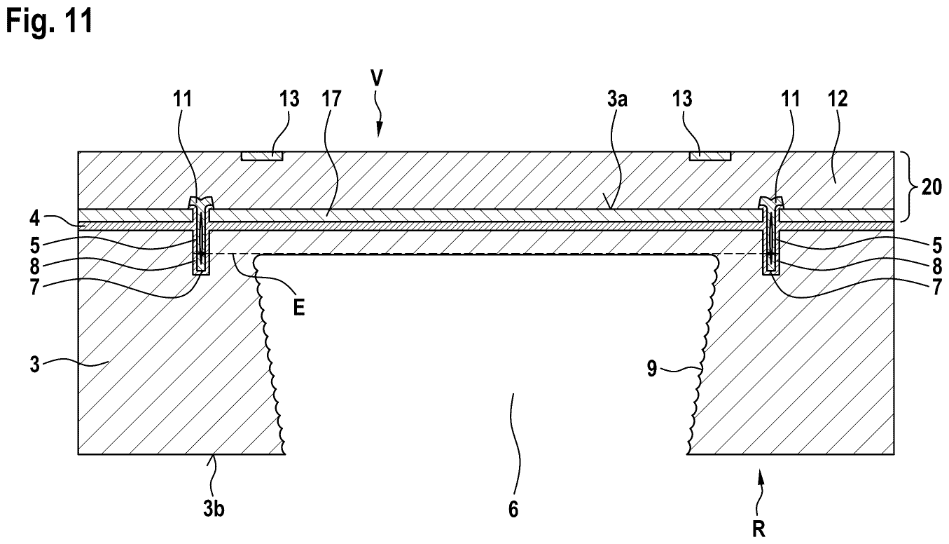

FIG. 11 shows an intermediate state of the component 1 during the production of the substrate recess 6 by means of a stage-by-stage trench process which has a plurality of anisotropic etching stages 9 and one isotropic etching stage 10, whereby the production of the substrate recess 6 is precisely controllable and efficient. The trench process can, for example, be carried out using a plasma etching process. An anisotropic etching stage 9 can have an etching step and a passivation step in order to allow an anisotropic etching direction substantially perpendicular to the rear-side substrate surface 3b. For example, after each etching step, a polymer deposition can be carried out on the wall faces of the substrate recess 6. The trench process can, for example, be carried out as a time-controlled high-rate trench process. As can be seen in FIG. 11, the etching cycle is continued with anisotropic etching stages 9 until the substrate recess 6 has reached a plane E of the vertical etch stop structure 5. Subsequently, a switch to an isotropic etching stage 10 takes place, which leads to the intermediate state of the component 1 shown in FIG. 12.

In FIG. 12, it can be seen that the isotropic etching stage 10 has resulted in a vertical and lateral expansion of the substrate recess 6 in a bottom region 15 to the horizontal etch stop structure 4 and to the vertical etch stop structure 5. The isotropic etching process stops on the one hand at the horizontal etch stop structure 4 and on the other hand at the vertical etch stop structure 5 so that the diaphragm 2 provided above the horizontal etch stop structure 4 is not affected by an etching attack, and its diaphragm contour 2a is still sharply delimited by the vertical etch stop structure 5.

It can be seen in FIG. 13 that the horizontal etch stop structure 4 and the vertical etch stop structure 5 were subsequently removed in regions in order to complete the exposure of the diaphragm 2 and to provide a pure silicon diaphragm having high sensitivity. The removal of the etch stop material of the horizontal etch stop structure 4 and of the vertical etch stop structure 5 can be carried out with a further etching process suitable for removing silicon dioxide material. The trench 7 now forms the circumferential trench structure 14 described above with reference to FIGS. 1 and 2, which trench structure sharply delimits the diaphragm contour 2a and allows any desired shaping of the diaphragm 2.

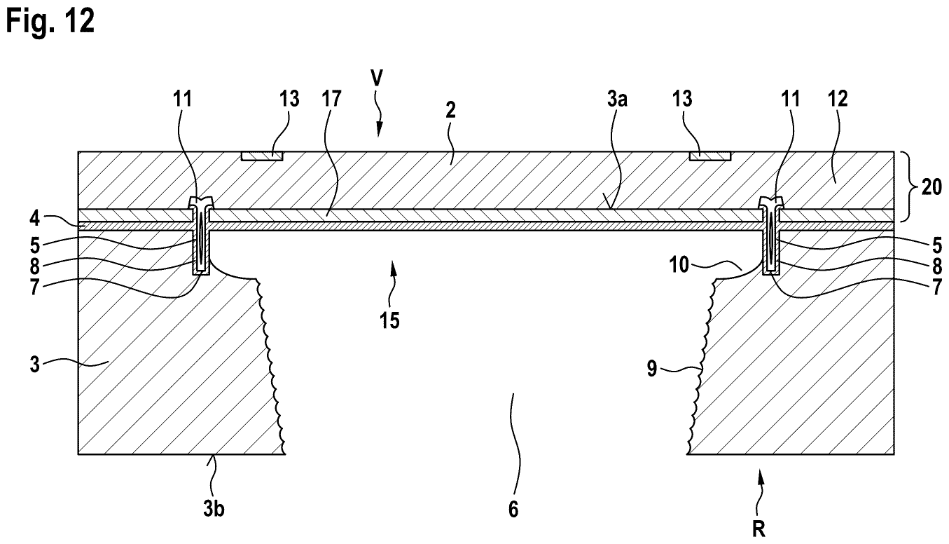

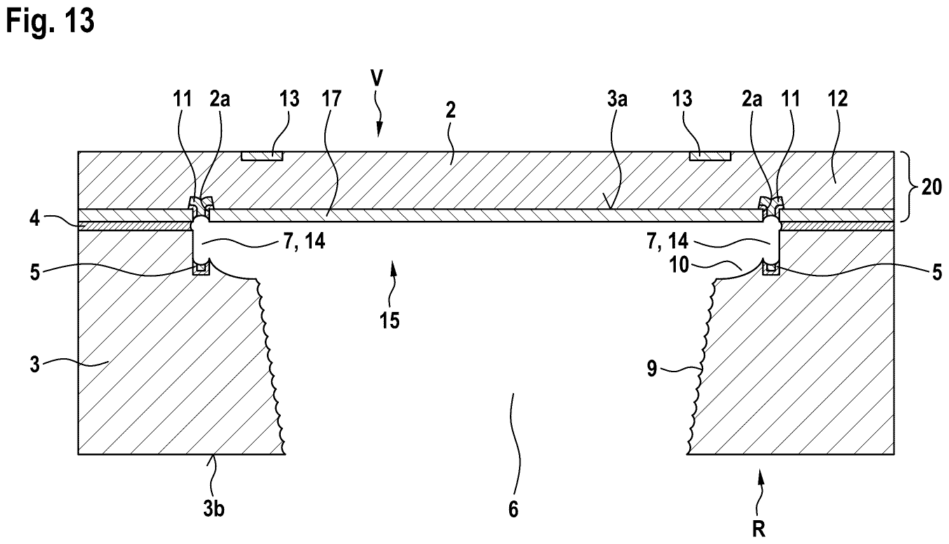

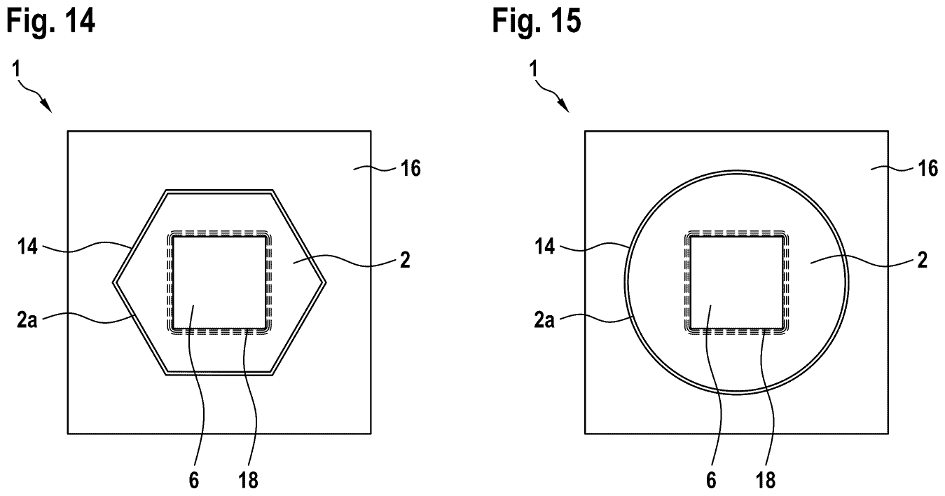

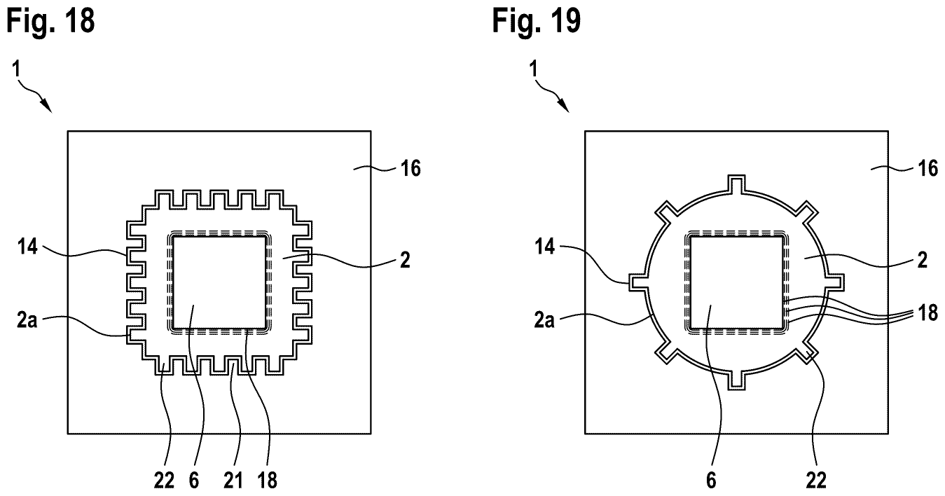

FIGS. 14 to 19 show further exemplary embodiments of microelectromechanical components 1 with a diaphragm 2 in partially transparent views from above in order to illustrate the design freedom of the shaping of the diaphragm 2 by means of the diaphragm contour 2a that can be precisely delimited with the trench structure 14. In particular, a geometric shape of the diaphragm contour 2a can deviate from a geometric cross-sectional shape of the substrate recess 6. An increasing edge rounding of a trench flank 18 of the substrate recess 6, for example, has no influence on the contour sharpness of the diaphragm contour 2a.

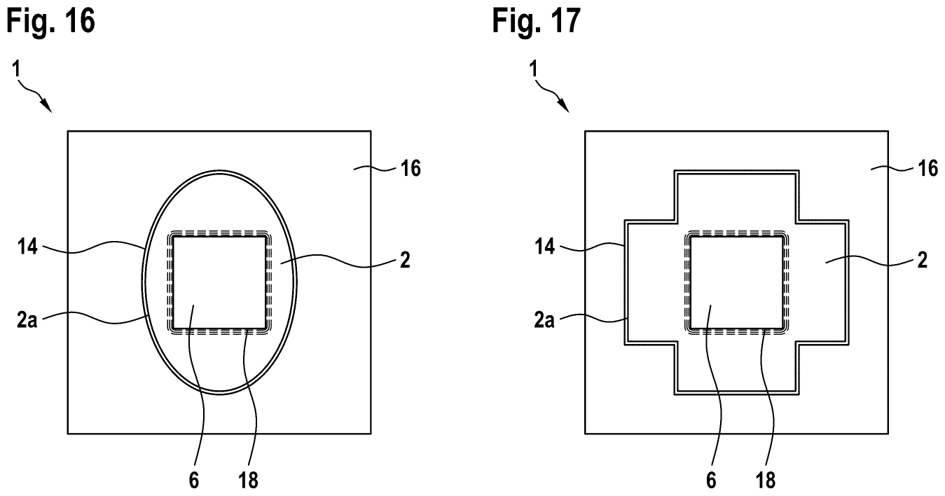

FIGS. 14 to 16 show possible geometry conversions between the cross-sectional shape of the substrate recess 6 and the geometric shape of the diaphragm 2. Thus, the substrate recess 6 in FIGS. 14 to 16 has a rectangular cross-sectional shape, while the diaphragm 2 has a hexagonal shape in FIG. 14, a circular shape in FIG. 15 and an elliptical shape in FIG. 16. Thanks to the possibility of designing the diaphragm independently of the substrate recess 6, the geometric shape of the diaphragm 2 can be adapted to individual requirements and operating conditions of the component 1. At the same time, this applies conversely to the substrate recess 6, the shape and dimensions of which can be adapted, for example, to the largest possible remaining rear-side substrate surface 3b in order to be able to provide the largest possible supporting or fastening face of the component 1, for example.

It can also be seen in FIGS. 17 to 19 that the diaphragm 2 can have a complex geometric shape beyond simple basic geometric shapes such as circles, regular rectangles or ellipses. For this purpose, a plurality of indentations 21 and/or projections 22, with which almost any desired filigree outer contours of the diaphragm 2 can be produced, can in particular be provided on a basic shape of the diaphragm contour 2a. As a result, it is possible to influence a characteristic diaphragm behavior very precisely or else to open up new technical fields of application for the microelectromechanical component 1.

15. (canceled)

16. A method for producing a microelectromechanical component having a diaphragm, the method comprising the following steps:
providing or producing a substrate with a substrate surface and a buried horizontal etch stop structure;
starting from a front side f the substrate, introducing a vertical etch stop structure extending substantially perpendicularly to the substrate surface, wherein the vertical etch stop structure predefines a lateral diaphragm contour of the diaphragm; and
etching, to expose the diaphragm, a substrate recess starting from a rear side of the substrate as far as the horizontal etch stop structure and the vertical etch stop structure.

17. The method according to claim 16, wherein the vertical etch stop structure is produced by producing a trench in the substrate and passivating side wall faces of the trench with a passivation layer.

18. The method according to claim 16, wherein the substrate is a silicon-on-insulator wafer.

19. The method according to claim 16, wherein the substrate recess is etched using a stage-by-stage trench process.

20. The method according to claim 19, wherein the stage-by-stage trench process has a plurality of anisotropic etching stages and one isotropic etching stage.

21. The method according to claim 16, wherein, after the substrate recess has been produced, the horizontal etch stop structure and/or the vertical etch stop structure are removed at least in regions.

22. The method according to claim 16, wherein the vertical etch stop structure is sealed with a sealing layer.

23. The method according to claim 22, wherein, after the vertical etch stop structure has been produced or after the produced vertical etch stop structure has been sealed, the substrate surface on the front side of the substrate is exposed at least in regions.

24. The method according to claim 16, wherein a functional layer is applied to or produced on the substrate, with which functional layer the vertical etch stop structure is enclosed and a diaphragm layer is formed.

25. The method according to claim 16, wherein at least one measuring element is applied in the diaphragm at a predetermined distance from the vertical etch stop structure.

26. A microelectromechanical component, comprising:
a substrate; and
a diaphragm, wherein a lateral diaphragm contour of the diaphragm is delimited by a vertical trench structure and, starting from a rear side of the substrate that faces away from the diaphragm, a substrate recess runs through the substrate and merges laterally into the vertical trench structure at least in a bottom region facing the diaphragm.

27. The microelectromechanical component according to claim 26, wherein the microelectromechanical component is a sensor component and/or as an actuator component.

28. The microelectromechanical component according to claim 26, wherein the microelectromechanical component is a pressure sensor.

29. The microelectromechanical component according to claim 26, wherein a geometric shape of the diaphragm contour deviates from a geometric cross-sectional shape of the substrate recess.

30. The microelectromechanical component according to claim 26, wherein the diaphragm contour has a complex geometric shape with at least one indentation and/or at least one projection.
